(19) United States
(12) Patent Application Publication
(10) Pub. No.: US 2004/0164311 A1
(43) Pub. Date: Aug. 26, 2004

(54) Light emitting apparatus

(75) Inventor: Toshiya Uemura, Aichi-ken (JP)

Correspondence Address: MCGINN & GIBB, PLLC, 8321 OLD COURTHOUSE ROAD, SUITE 200, VIENNA, VA, 22182-3817, US

(73) Assignee: Toyoda Gosei Co., Ltd., Aichi-ken (JP)

(21) Appl. No.: 10/774,389

(22) Filed: Feb. 10, 2004

(30) Foreign Application Priority Data
Feb. 20, 2003 (JP) 2003-043109

(51) Int. Cl. H01L 27/15

(52) U.S. Cl. 257/99; 257/79

(57) ABSTRACT

A light emitting apparatus has: a semiconductor light emitting element that radiates light from its light emission surface provided on the opposite side to its electrode forming surface; lead frames that are electrically connected to electrodes formed on the electrode forming surface through wires; a transparent structure that is optically connected with the light emission surface and has a light distribution characteristic based on its three-dimensional shape; and light transmitting resin that seals the semiconductor light emitting element and the transparent structure.

The present application is based on Japanese patent application No. 2003-043109, the entire contents of which are incorporated herein by reference.

### BACKGROUND OF THE INVENTION

1. Field of the Invention

This invention relates to a light emitting apparatus, and particularly to a light emitting apparatus that uses a semiconductor light emitting element (flip-chip bonding type LED chip) to radiate light from its light emission surface provided on the opposite side to its electrode forming surface.

2. Description of the Related Art

Japanese patent application laid-open No. 10-190065 (herein referred to as prior art 1) discloses a light emitting apparatus that light emitted from LED chip is wavelength-converted by phosphor (See FIG. 2 ibid.).

FIG. 1 is a cross sectional view showing the light emitting apparatus 20 disclosed in prior art 1. The light emitting apparatus 20 is composed of: LED chip 23 housed in concave portion 22 of package 21; first coating 24 and second coating 25 that are of light transmitting resin and embedded in the concave portion 22; external electrodes 26 exposed out of the package 21; and bonding wires 27 that electrically connect the external electrode 26 and LED chip 23. The second coating 25 contains phosphor 25A to absorb visible light emitted from the LED chip 23 and to radiate wavelength-converted light from there. Thus, by wavelength-converting light emitted from the LED chip 23, visible light with different color can be obtained. For example, when blue light emitted from the blue LED chip 23 passes through the second coating 25 containing phosphor 25A that absorbs blue light and then radiates yellow light, blue light and wavelength-converted yellow light are mixed and, therefore, white light as complementary color can be obtained.

Japanese patent application laid-open No. 2000-22222 (herein referred to as prior art 2) discloses another light emitting apparatus that light is radiated from the transparent substrate side opposite to the electrode forming surface (See FIG. 1 ibid.)

FIG. 2 is a cross sectional view showing the light emitting apparatus 30 disclosed in prior art 2. The light emitting apparatus 30 is composed of: a pair of lead frames 31 with reflection horns 31A, 31B; LED chip 32 that GaN system light emitting layer 32B is formed on transparent substrate 32A such as sapphire; wavelength conversion element 33 that is disposed contacting the transparent substrate 32A of LED chip 32; and transparent sealing material 34 that is molded covering the lead frames 31, LED chip 32 and wavelength conversion element 33.

The reflection horns 31A, 31B have engagement claws 31c, 31d to fix the wavelength conversion elements 33 on the entire inner circumference of reflection frame. They press sheet-like base film 34A of the wavelength conversion element 33 by the engagement claws 31c, 31d to fix it securely.

The LED chip 32 has electrodes 32a, 32b that are electrically connected with the bottom surfaces 31a, 31b of reflection horns 31A, 31b through bumps (not shown).

The wavelength conversion element 33 is composed of the base film 33A and wavelength conversion layer 33B formed on the base film 33A, the wavelength conversion layer 33B being made by uniformly mixing wavelength conversion material and resin binding agent, coated on the base film 32A, then hardened. The wavelength conversion element 33 is disposed in the reflection horns 31A, 31B to allow the wavelength conversion layer 33B to contact the transparent substrate 32A of LED chip 32.

In this light emitting apparatus, the light extraction efficiency can be enhanced by taking out light from the transparent substrate side of LED chip. Further, with the wavelength conversion material formed as layer, equalization and efficiency in wavelength conversion can be enhanced. Therefore, unevenness in emission color caused by nonuniformity of wavelength conversion can be significantly reduced.

However, the conventional light emitting apparatuses have next problems.

(1) In the light emitting apparatus 20 disclosed in prior art 1, the center portion of second coating 25 is made thicker than the edge portion. Therefore, phosphor blocks the radiation of light. Also, electrodes (not shown) formed on LED chip 23 block the radiation of light. Thus, in the wire-bonding structure, since the light extraction efficiency lowers, it is difficult to obtain sufficient brightness.

(2) In the light emitting apparatus 30 disclosed in prior art 2, the steps of bump forming, inversion of bonding surface and positioning are needed in the mounting of LED chip. Thus, the manufacturing process is complicated and the bump forming and positioning steps need high precision. Further, an expensive flip-chip bonder is needed to conduct the process. The manufacturing cost is increased.

Thus, the wire-bonding structure as disclosed in prior art 1 is advantageous in aspect of manufacturing. However, prior art 1 (wire-bonding structure) has a problem that it is difficult to obtain sufficient brightness due to the lowering of light extraction efficiency.

### SUMMARY OF THE INVENTION

It is an object of the invention to provide a light emitting apparatus that can offer high light extraction efficiency while having a wire-bonding structure.

According to one aspect of the invention, a light emitting apparatus comprises:

a semiconductor light emitting element that radiates light from its light emission surface provided on the opposite side to its electrode forming surface;

lead frames that are electrically connected to electrodes formed on the electrode forming surface through wires;

a transparent structure that is optically connected with the light emission surface and has a light distribution characteristic based on its three-dimensional shape; and

light transmitting resin that seals the semiconductor light emitting element and the transparent structure.

According to another aspect of the invention, a light emitting apparatus comprises:

a semiconductor light emitting element that radiates light from its light emission surface provided on the opposite side to its electrode forming surface;

lead frames that are electrically connected to electrodes formed on the electrode forming surface through wires;

a transparent structure that is optically connected with the light emission surface and has a light distribution characteristic based on its three-dimensional shape; and

light transmitting resin that seals the semiconductor light emitting element and the transparent structure, the light transmitting resin including a phosphor to wavelength-convert light emitted from the semiconductor light emitting element.

### BRIEF DESCRIPTION OF THE DRAWINGS

The preferred embodiments according to the invention will be explained below referring to the drawings, wherein:

FIG. 1 is a cross sectional view showing the conventional light emitting apparatus disclosed in prior art 1;

FIG. 2 is a cross sectional view showing the other light emitting apparatus disclosed in prior art 2;

FIG. 3 is a cross sectional view showing a light emitting apparatus 1 in a first preferred embodiment of the invention;

FIG. 4 is a cross sectional view showing part of the light emitting apparatus in the first embodiment;

FIG. 5 is a cross sectional view showing part of a light emitting apparatus in a second preferred embodiment of the invention;

FIG. 6 is a cross sectional view showing part of a light emitting apparatus in a third preferred embodiment of the invention;

FIG. 7 is a cross sectional view showing part of a light emitting apparatus in a fourth preferred embodiment of the invention;

FIG. 8 is a cross sectional view showing part of a light emitting apparatus in a fifth preferred embodiment of the invention;

FIG. 9 is a cross sectional view showing part of a light emitting apparatus in a sixth preferred embodiment of the invention;

FIG. 10 is a cross sectional view showing part of a light emitting apparatus in a seventh preferred embodiment of the invention;

FIG. 11 is a cross sectional view showing part of a light emitting apparatus in an eighth preferred embodiment of the invention;

FIG. 12 is a cross sectional view showing part of a light emitting apparatus in a ninth preferred embodiment of the invention;

FIGS. 13A to 13C are top views showing part of a light emitting apparatus in a tenth preferred embodiment of the invention; and

FIG. 14 is a cross sectional view showing part of a light emitting apparatus in an eleventh preferred embodiment of the invention.

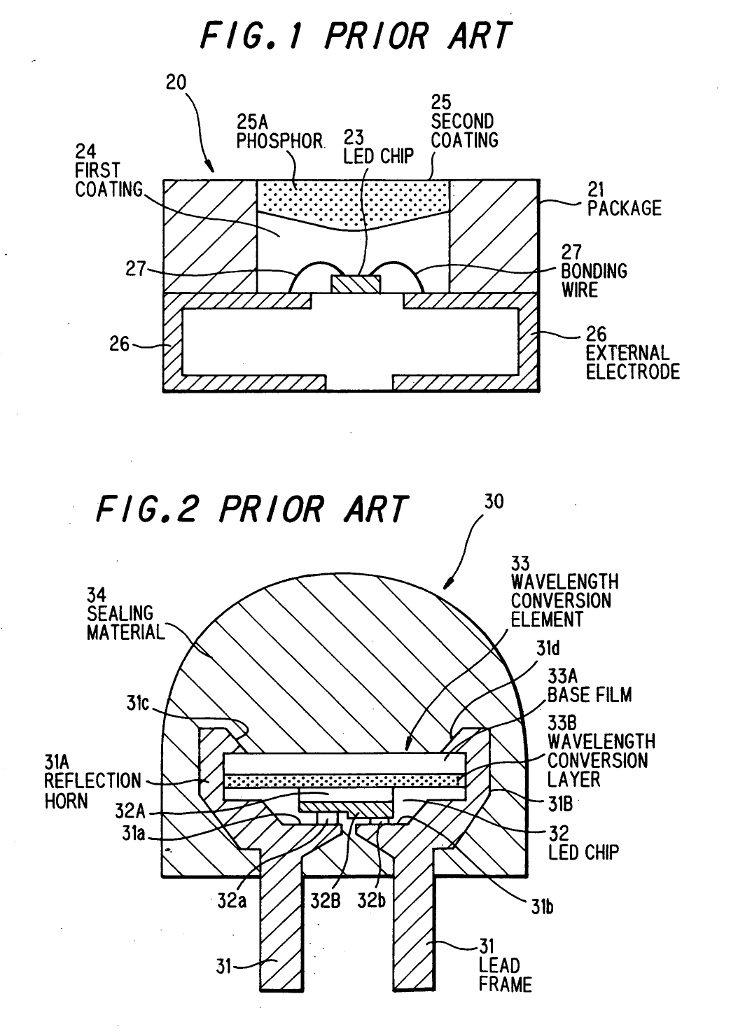

### DETAILED DESCRIPTION OF THE PREFERRED EMBODIMENTS

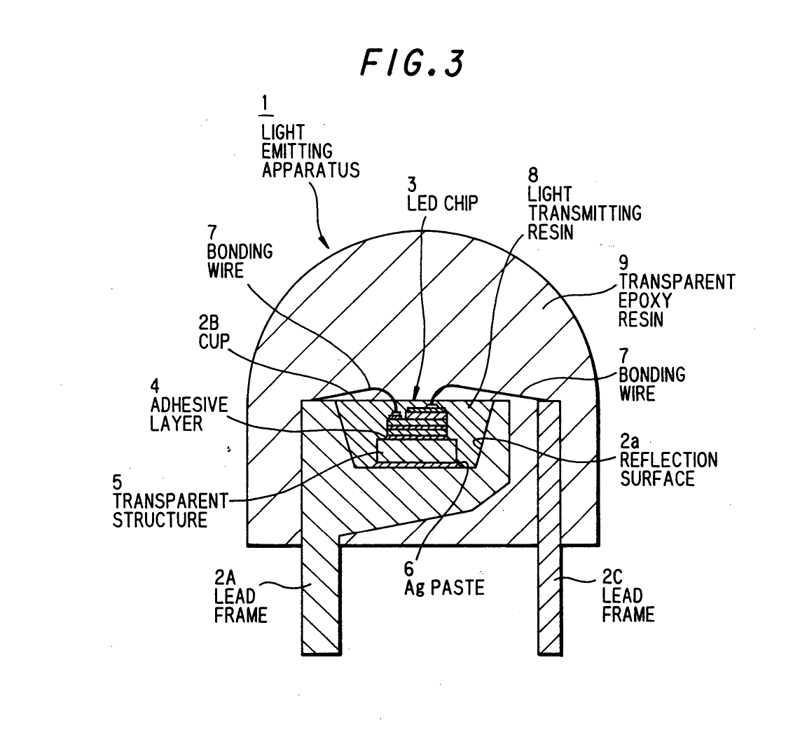

FIG. 3 is a cross sectional view showing a light emitting apparatus 1 in the first preferred embodiment of the invention. The light emitting apparatus 1 is composed of: lead frames 2A and 2C of metallic material; a cup 2B that is formed on the tip of the lead frame 2A to house a LED chip 3; a transparent structure 5 that is bonded to the LED chip 3 through light transmitting adhesive layer 4; Ag paste 6 that fixes the transparent structure 5 to the bottom of cup 2B; bonding wires 7 that electrically connects between the electrodes of LED chip 3 and the lead frames 2A, 2C; light transmitting resin 8 that is filled in the cup 2B to seal the LED chip 3 and transparent structure 5; and transparent epoxy resin 9 that integrally molds the lead frames 2A, 2A and bonding wires 7.

The lead frames 2A, 2C are of metallic material such as copper alloy with good thermal conductivity. The cup 2B has reflection surface 2a formed on its inner surface.

The LED chip 3 is, for example, of gallium nitride system compound semiconductor such as GaN, GaAlN, InGaN and InGaAlN or ZnSe and emits blue system light with a wavelength of 450 to 480 nm. The LED chip 3 is a flip-chip bonding type LED that light is mainly taken out from a sapphire substrate on the opposite side to the electrode forming surface. The transparent structure 5 is bonded to the sapphire substrate through adhesive layer 4.

The adhesive layer 4 serves to optically connect the LED chip 3 with the transparent structure 5 by adhesion. It may be of transparent adhesives such as silicon resin, epoxy resin, acrylic resin and ceramics paste.

The transparent structure 5 is formed a rectangular solid and is of light transmitting material such as SiO₂, Al₂O₃, SiC, Si₃N₄, AlN, ZrO₂, borosilicate glass and alumino-silicate glass. It has a size bigger than the LED chip 3. It preferably has a thickness in the range of half the chip thickness to twice the length of chip's shorter side. The transparent structure 5 may have another three dimensional shape other than rectangular solid.

Light transmitting resin 8 is of epoxy resin and contains Ce:YAG (yttrium-aluminum-garnet) as yellow phosphor. It may be of silicon resin, which becomes transparent after hardening, other than epoxy resin.

Transparent epoxy resin 9 is molded to have a lamp form in order to converge light radiated upward from the LED chip 3 and cup 2B.

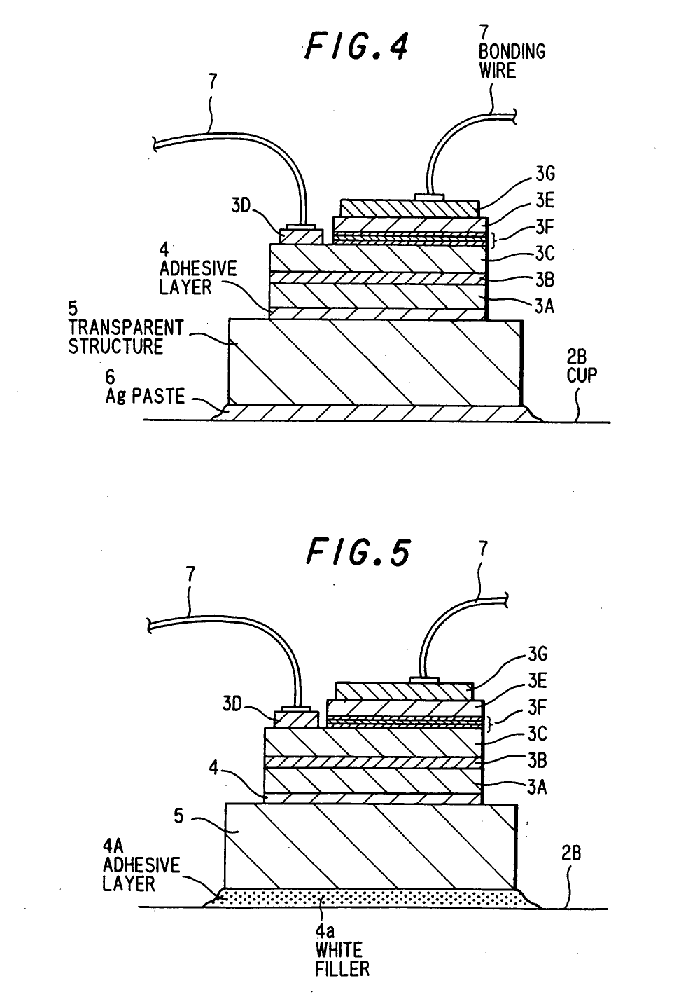

FIG. 4 is a cross sectional view showing part of the light emitting apparatus in the first embodiment. In FIG. 4, light transmitting resin 8 around the LED ship 3 is omitted. The LED chip 3 is composed of: sapphire substrate 3A; Al buffer layer 3B; n-type semiconductor layer 3C; n-electrode 3D; p-type semiconductor layer 3E; multiple layers 3F including light emitting layer; and p-electrode 3G. Bonding wires 7 are bonded to the n-electrode 3D and p-electrode 3G. The n-electrode 3D and p-electrode 3G each have such a thickness that light does not transmit through.

In manufacturing the light emitting apparatus 1, at first, metallic material of copper alloy is punched to provide the shape of lead frames 2A, 2C, and then the cup 2B is formed on the lead frame 2A by indentation method. Then, the transparent structure 5 is bonded to the cup 2B through Ag paste 6. Then, the LED chip 3 is bonded to the transparent structure 5 through adhesive layer 4 applied therebetween. Then, the bonding wires 7 are bonded to electrically connect between the n-electrode 3D and lead frame 2A and between the p-electrode 3G and lead frame 2C. Then, by injecting epoxy resin including phosphor into the cup 2B and hardening it, light transmitting resin 8 is formed. Then, it is moved upward to a metallic mold where transparent epoxy resin 9 is formed while holding the lead frames 2A, 2C. Then, after positioning the lead frames 2A, 2C to the metallic mold and inserting it thereinto, transparent epoxy resin 9 is injected into the metallic mold. After hardening the epoxy resin, the light emitting apparatus 1 is taken out of the metallic mold.

In mounting the LED chip 3 on the lead frame 2A, the LED chip 3 may be previously bonded to the transparent structure 5. For example, if the transparent structure 5 is formed cutting a wafer-like base, the LED chip 3 may be attached on the base. In this case, by cutting the base into predetermined size pieces, a chip portion with the LED chip 3 and transparent structure 5 attached integrally is obtained. The chip portion is bonded to the lead frame 2A through Ag paste 6. In this manner, the LED chip 3 and transparent structure 5 can be simultaneously mounted on the lead frame 2A by one step.

The operation of light emitting apparatus of the first embodiment will be explained below.

A driving section (not shown) applies a drive voltage to the n-electrode 3D and p-electrode 3G of LED chip 3. The multiple layers 3F emit light by planar emission based on the drive voltage. Light emitted from the multiple layers 3F passes mainly through the sapphire substrate 3A, entering to the transparent structure 5. The transparent structure 5 reflects part of entered light inside it, then discharging it from its side surface and its upper face close to the bonding surface to LED chip 3. Part of light discharged from the transparent structure 5 is applied to phosphor in light transmitting resin 8. The phosphor is excited by applied light and radiates excited light with a wavelength of 550 to 580 nm. This exited light is mixed with light radiated from the transparent structure 5 to provide white light. White light is reflected on the reflection surface 2a of cup 2B, and then radiated upward to transparent epoxy resin 9.

The abovementioned light emitting apparatus in the first embodiment has next effects.

(1) Since the transparent structure 5 of rectangular solid is bonded to the sapphire substrate through the adhesive layer 4 and is fixed to the cup 2B, the LED chip 3 can be easily connected to the lead frames 2A, 2C through the bonding wires 7. Further, since accurate positioning needed in bump forming step or in LED chip mounting step in case of flip-chip bonding is not necessary, the manufacturing process can be simplified. With the simplified manufacturing process, the manufacturing cost can be reduced and the producibility can be enhanced.

(2) Since light is radiated through the transparent structure 5, the light emission density lowers and a light distribution characteristic different from that of LED chip 3 by itself can be obtained. Therefore, light can be efficiently applied to phosphor in light transmitting resin 8. Due to this, yellow light wavelength-converted is uniformly mixed with blue light and, thereby, unevenness in emission color can be prevented.

(3) Since the light emission area is enlarged due to the transparent structure 5, the light shield effect caused by covering the LED chip with phosphor can be reduced and, thereby, the brightness can be enhanced.

Although, in the first embodiment mentioned above, the light emitting apparatus 1 uses the nontransparent n-electrode 3D and p-electrode 3G, the n-electrode 3D and p-electrode 3G may be transparent and the LED chip 3 may be provided with transparent substrate.

FIG. 5 is a cross sectional view showing part of a light emitting apparatus in the second preferred embodiment of the invention. Different from the light emitting apparatus 1 of the first embodiment, the light emitting apparatus 1 of the second embodiment is composed such that the transparent structure 5 is bonded to the cup 2B through a adhesive layer 4A (composed of adhesive resin) with white filler 4a of alumina etc mixed as light diffusion material. Like components are indicated by same numerals used in the first embodiment, and explanations thereof are omitted below.

In the second embodiment, adding to the effects of the first embodiment, the light diffusion property at the bottom of transparent structure 5 can be varied by the light diffusion material being mixed into the adhesive layer 4A. Furthermore, by using adhesive resin (white paste) or transparent adhesive resin (transparent paste) with white filler mixed therein instead of Ag paste 6, stable brightness can be obtained over the long term. This is because, in case of Ag paste, Ag filler is oxidized by heating or light radiated from LED and the reflectivity deteriorates with time.

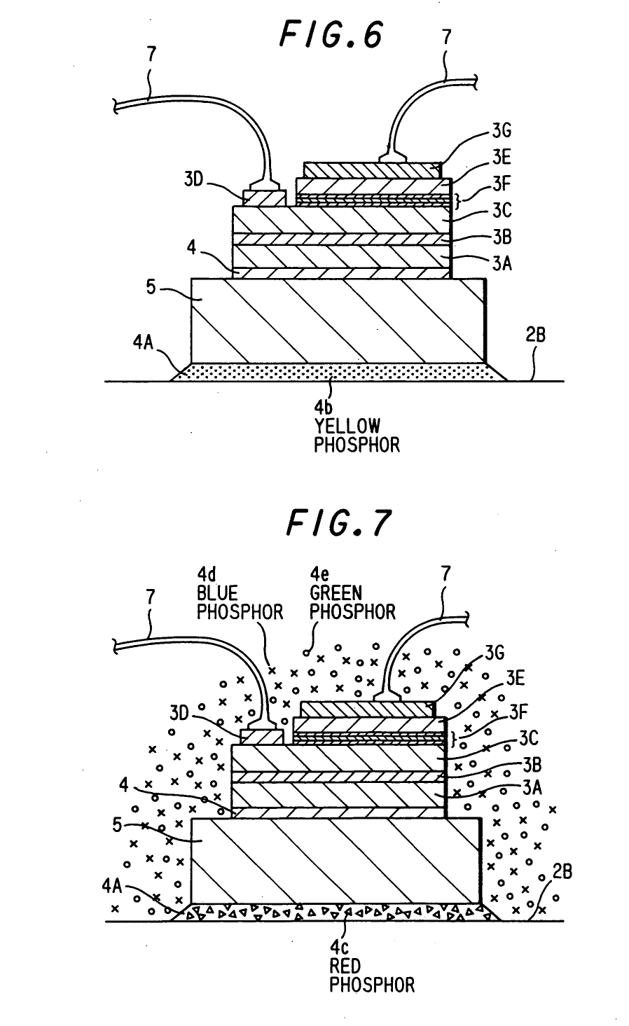

FIG. 6 is a cross sectional view showing part of a light emitting apparatus in the third preferred embodiment of the invention. Different from the light emitting apparatus 1 of the second embodiment, the light emitting apparatus 1 of the third embodiment is composed such that the transparent structure 5 is bonded to the cup 2B through a adhesive layer 4A (composed of adhesive resin) with yellow phosphor 4b of same kind as included in the light transmitting resin 8 mixed therein. Like components are indicated by same numerals used in the second embodiment, and explanations thereof are omitted below.

In the third embodiment, adding to the effects of the first embodiment, excited light can be also radiated from the yellow phosphor 4b in the adhesive layer 4A. Thus, the amount of phosphor mixed in light transmitting resin 8 can be reduced and, thereby the light extraction efficiency can be further enhanced to increase the brightness. This is because the light shield effect caused by phosphor mixed in light transmitting resin 8 can be reduced. Further, the light diffusion property at the bottom of transparent structure 5 can be further enhanced.

FIG. 7 is a cross sectional view showing part of a light emitting apparatus in the fourth preferred embodiment of the invention. Different from the light emitting apparatus 1 of the second embodiment, the light emitting apparatus 1 of the fourth embodiment is composed such that the LED chip 3 emits ultraviolet light with a wavelength of around 380 nm, red phosphor 4c, blue phosphor 4d and green phosphor 4e to be excited by ultraviolet light are used to radiate white light, the red phosphor 4c is mixed in the adhesive layer 4, and the blue phosphor 4d and green phosphor are mixed in light transmitting resin 8. Like components are indicated by same numerals used in the first and second embodiments, and explanations thereof are omitted below.

The red phosphor 4c is, for example, Y(P,V)O₄:Eu or Y₂O₂S:Eu.

The blue phosphor 4d is, for example, (Ba, Ca, Mg)₁₀ (PO₄)₆C₁₂:Eu or Sr₂P₂O₇:Eu.

The green phosphor 4e is, for example, (Ba, Mg)₂Al₁₆C₂₇:Eu or BaMgAl₁₆C₂₇:Eu.

In the fourth embodiment, adding to the effects of the first embodiment, the amount of phosphor mixed in light transmitting resin 8 can be reduced by mixing red phosphor 4c with lowest excitation efficiency in the adhesive layer 4A and, thereby the light extraction efficiency can be further enhanced to increase the brightness. With regard to the deposition of phosphor, at least one of red, blue and green phosphors may be selectively mixed in the adhesive layer 4A and the remainder may be mixed in light transmitting resin 8. Also, red, blue and green phosphors may be mixed in light transmitting resin 8.

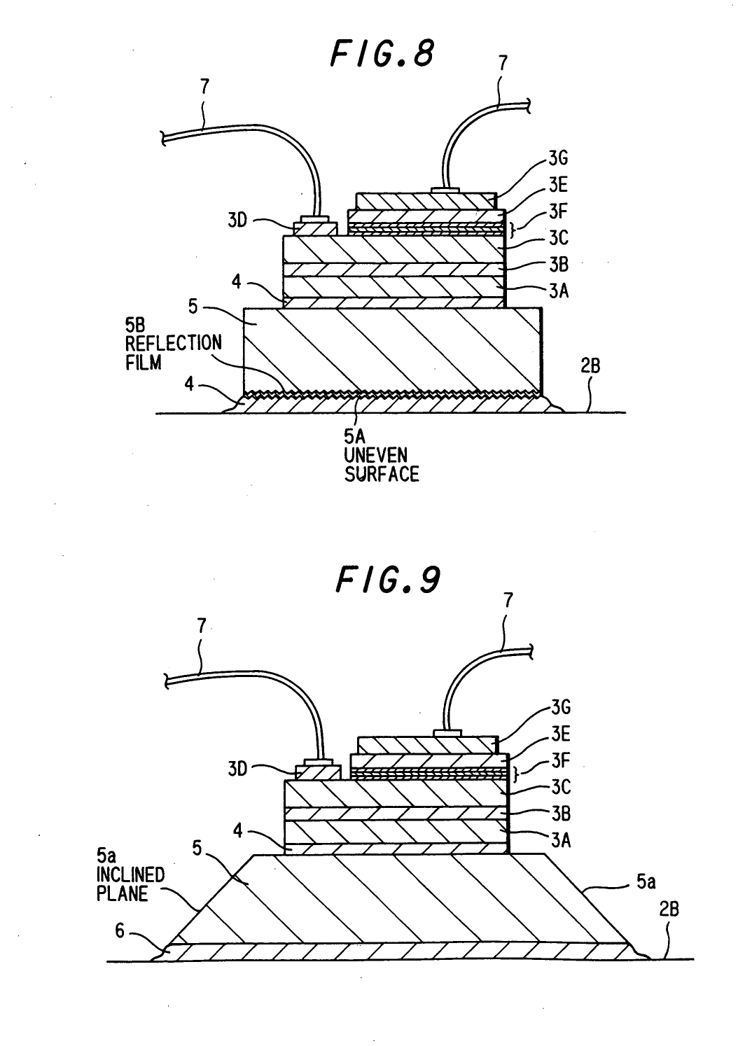

FIG. 8 is a cross sectional view showing part of a light emitting apparatus in the fifth preferred embodiment of the invention. Different from the light emitting apparatus 1 of the first embodiment, the light emitting apparatus 1 of the fifth embodiment is composed such that the transparent structure 5 has microscopic uneven surface 5A formed at the bottom and there is provided a reflection film 5B, as aluminum thin film, with a thickness of about 1500 Å. Like components are indicated by same numerals used in the first embodiment, and explanations thereof are omitted below.

In the fifth embodiment, adding to the effects of the first embodiment, the light diffusion property and reflectivity at the bottom of transparent structure 5 can be further enhanced based on the shape of microscopic uneven surface 5A and light reflection film 5B. Further, Ag paste may be used to bond the transparent structure 5 to the cup 2B since the transparent structure 5 has the light diffusion structure and light reflection film.

FIG. 9 is a cross sectional view showing part of a light emitting apparatus in the sixth preferred embodiment of the invention. Different from the light emitting apparatus 1 of the first embodiment, the light emitting apparatus 1 of the sixth embodiment is composed such that the transparent structure 5 has four inclined planes 5a with a trapezoidal cross section to enlarge its bottom portion in the front, back, right and left directions. Like components are indicated by same numerals used in the first embodiment, and explanations thereof are omitted below.

In the sixth embodiment, adding to the effects of the first embodiment, light can be efficiently radiated in the horizontal and vertical directions based on the shape of inclined planes 5a. The transparent structure 5 may have the microscopic uneven surface and light reflection surface at the bottom as described in the third embodiment.

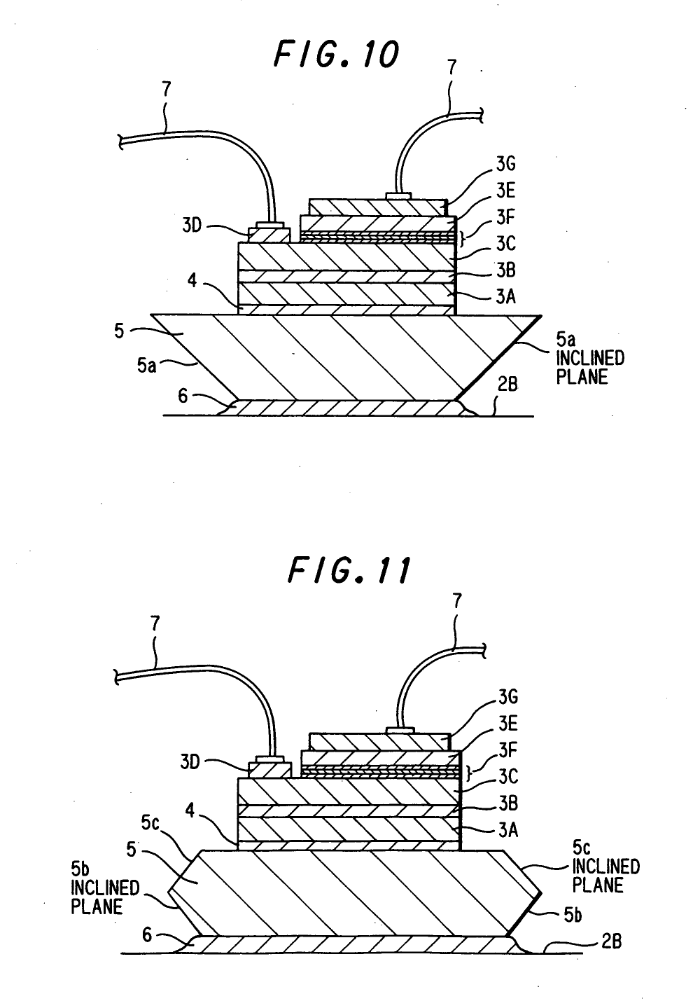

FIG. 10 is a cross sectional view showing part of a light emitting apparatus in the seventh preferred embodiment of the invention. Different from the light emitting apparatus 1 of the sixth embodiment, the light emitting apparatus 1 of the seventh embodiment is composed such that the transparent structure 5 has four inclined planes 5a with an inverted trapezoidal cross section to enlarge its top portion in the front, back, right and left directions. Like components are indicated by same numerals used in the sixth embodiment, and explanations thereof are omitted below.

In the seventh embodiment, adding to the effects of the first embodiment, light can be efficiently radiated upward by reflecting light transmitting through the transparent structure 5 on the inclined planes 5a. The transparent structure 5 may have the microscopic uneven surface and light reflection surface at the bottom as described in the third embodiment.

FIG. 11 is a cross sectional view showing part of a light emitting apparatus in the eighth preferred embodiment of the invention. Different from the light emitting apparatus 1 of the sixth embodiment, the light emitting apparatus 1 of the eighth embodiment is composed such that the transparent structure 5 has four inclined planes 5b, 5c with a pentagonal cross section to enlarge its center portion in the front, back, right and left directions. Like components are indicated by same numerals used in the sixth embodiment, and explanations thereof are omitted below.

In the eighth embodiment, adding to the effects of the first embodiment, light can be efficiently radiated in the horizontal and vertical directions based on the shape of inclined planes 5b, 5c. The transparent structure 5 may have the microscopic uneven surface and light reflection surface at the bottom as described in the third embodiment.

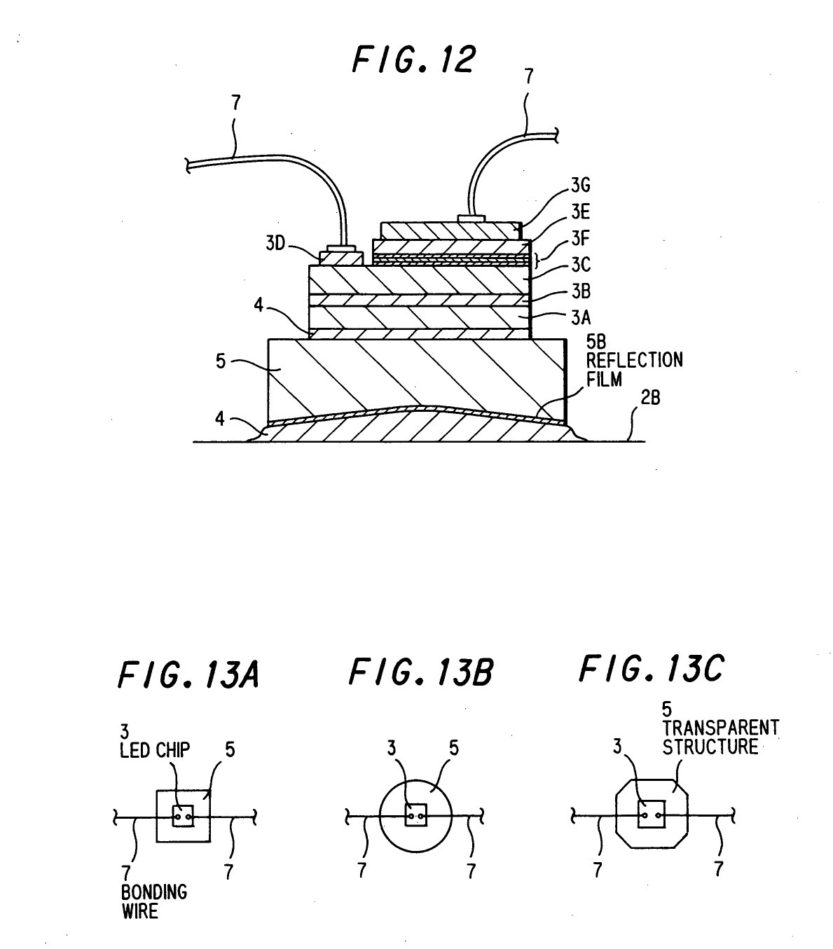

FIG. 12 is a cross sectional view showing part of a light emitting apparatus in the ninth preferred embodiment of the invention. Different from the light emitting apparatus 1 of the first embodiment, the light emitting apparatus 1 of the ninth embodiment is composed such that the transparent structure 5 has a concaved surface at the center of bottom and a reflection film 5B formed on the concave surface. Like components are indicated by same numerals used in the first embodiment, and explanations thereof are omitted below.

The reflection film 5B is, for example, aluminum film formed by deposition and preferably has effective reflectivity and unevenness to diffuse light. It may be formed by another film forming method such as sputtering.

In the ninth embodiment, adding to the effects of the first embodiment, light can be efficiently radiated upward from the side surface of the transparent structure 5 by reflecting light entered to the transparent structure 5 on the reflection film 5B. The transparent structure 5 may be formed to have a trapezoidal cross section as described in the fourth and fifth embodiments and, thereby, the light extraction efficiency in the horizontal and vertical directions can be enhanced.

FIGS. 13A to 13C are top views showing part of a light emitting apparatus in the tenth preferred embodiment of the invention. Although in the first to ninth embodiments the transparent structure 5 has a rectangular solid shape or trapezoidal cross section as shown in FIG. 13A, it may have another shape. For example, it may have a round shape as shown in FIG. 13B or octagonal shape as shown in FIG. 13C, or it may have another shape according to required light distribution characteristic or use.

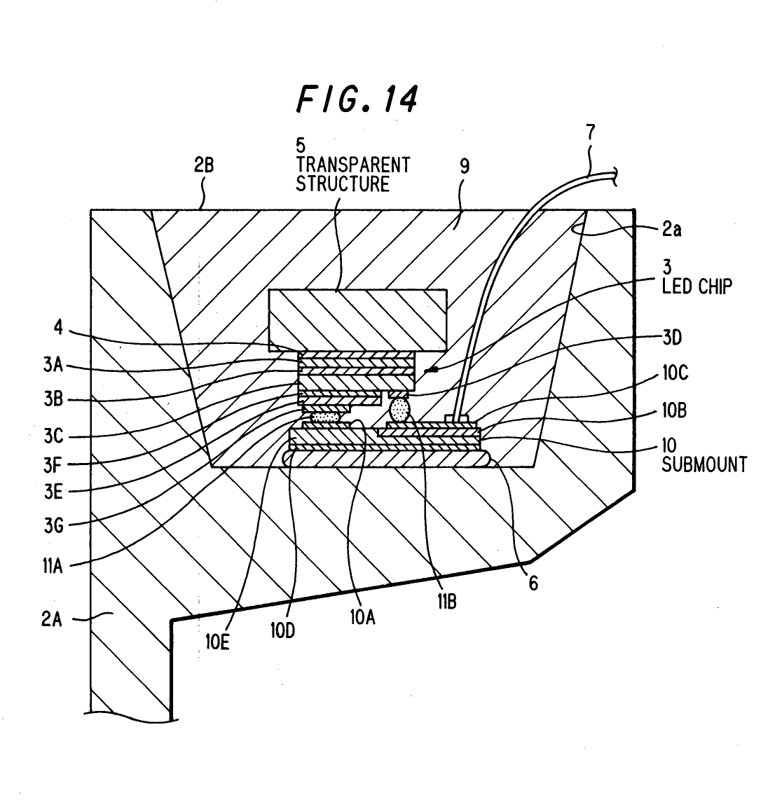

FIG. 14 is a cross sectional view showing part of a light emitting apparatus in the eleventh preferred embodiment of the invention. In the eleventh embodiment, the LED chip 3 is bonded to the transparent structure 5 through the adhesive layer 4, and the LED chip 3 is flip-chip mounted on a submount element 10 through Au bumps 11A, 11B. With the transparent structure 5 disposed above the LED chip 3, the light extraction efficiency can be enhanced. Like components are indicated by same numerals used in the first embodiment, and explanations thereof are omitted below.

The submount 10 is of n-type silicon substrate and operates as Zener diode to protect the LED chip 3 from electrostatic. It is also composed of: n-electrode 10A connected with the p-electrode 3G through Au bump 11A; p-type semiconductor layer 10B; p-electrode 10C connected with the n-electrode 3D through Au bump 11B; n-electrode 10D electrically connected with the cup 2B through Ag paste 6; and n-type semiconductor layer 10E.

In the eleventh embodiment, the light discharging surface of LED chip 3 is disposed on the opening side of cup 2B by virtue of the flip-chip bonding, and the transparent structure 5 is bonded to the surface of sapphire substrate 3A as light discharging surface. Thereby, light can be taken out from the side surface, bottom surface and top surface of transparent structure 5 and, therefore, the light discharging area can be enlarged.

In the light emitting apparatus with LED chip 3 flip-chip bonded, the light shield effect caused by covering the light source with phosphor can be reduced due to the transparent structure 5 bonded to the light discharging surface of LED chip 3. The transparent structure 5 may be formed to have a lamp shape on its upper portion to offer a property to converge light vertically upward.

Although, in the above embodiments, the light emitting apparatus 1 is mounted on the lead frames, it may be mounted on a substrate (circuit board).

Phosphor may be contained in transparent epoxy resin 9 instead of light transmitting resin 8. Alternatively, phosphor may be not contained in any of transparent epoxy resin 9 and light transmitting resin 8.

The LED chip 3 may emit visible light of red or green color other than blue color, or ultraviolet light. Phosphor to be excited can be selected according to light to be radiated.

Although the invention has been described with respect to the specific embodiments for complete and clear disclosure, the appended claims are not to be thus limited but are to be construed as embodying all modifications and alternative constructions that may occur to one skilled in the art which fairly fall within the basic teaching herein set forth.

What is claimed is:

1. A light emitting apparatus, comprising:
a semiconductor light emitting element that radiates light from its light emission surface provided on the opposite side to its electrode forming surface;
lead frames that are electrically connected to electrodes formed on the electrode forming surface through wires;
a transparent structure that is optically connected with the light emission surface and has a light distribution characteristic based on its three-dimensional shape; and
light transmitting resin that seals the semiconductor light emitting element and the transparent structure.

2. The light emitting apparatus according to claim 1, wherein:
the transparent structure has a length in the horizontal direction greater than that of the semiconductor light emitting element.

3. The light emitting apparatus according to claim 1, wherein:
the transparent structure has a thickness of half that of the semiconductor light emitting element to twice the length of a shorter side of the semiconductor light emitting element.

4. The light emitting apparatus according to claim 1, wherein:
the transparent structure has a microscopic uneven surface to diffuse light.

5. The light emitting apparatus according to claim 1, wherein:
the transparent structure has a reflection layer formed on its surface.

6. The light emitting apparatus according to claim 1, wherein:
one of the lead frames has a cup portion, and
the transparent structure is fixed on the cup portion through adhesive resin with light diffusion material mixed therein.

7. The light emitting apparatus according to claim 1, wherein:
the electrodes do not transmit light.

8. A light emitting apparatus, comprising:
a semiconductor light emitting element that radiates light from its light emission surface provided on the opposite side to its electrode forming surface;
lead frames that are electrically connected to electrodes formed on the electrode forming surface through wires;
a transparent structure that is optically connected with the light emission surface and has a light distribution characteristic based on its three-dimensional shape; and
light transmitting resin that seals the semiconductor light emitting element and the transparent structure, the light transmitting resin including a phosphor to wavelength-convert light emitted from the semiconductor light emitting element.

9. The light emitting apparatus according to claim 8, wherein:
the light transmitting resin contains two or more kinds of phosphors.
